(19) United States
(12) Patent Application Publication
(10) Pub. No.: US 2022/0075529 A1
(43) Pub. Date: Mar. 10, 2022

(54) MEMORY SYSTEM, METHOD FOR THE OPERATION THEREOF

(71) Applicant: Harman Becker Automotive Systems GmbH, Karlsbad (DE)

(72) Inventor: Ivan Iliev IVANOV, Steinhoering (DE)

(73) Assignee: Harman Becker Automotive Systems GmbH, Karlsbad (DE)

(21) Appl. No.: 17/463,330

(22) Filed: Aug. 31, 2021

(30) Foreign Application Priority Data
Sep. 4, 2020 (DE) 102020123220.9

(51) Int. Cl. G06F 3/06

(52) U.S. Cl. CPC G06F 3/0616; G06F 3/0679; G06F 3/0653; G06F 3/0604

(57) ABSTRACT

A method for managing a memory for an onboard computer in a motor vehicle is provided. The method includes: determining, at regular time intervals, a degree of wear of the memory depending on an amount of data written into the memory; and if the degree of wear exceeds a specified target value: changing a coding of one or more cells of the memory from a physical coding of higher density to a physical coding of lower density.

### CROSS-REFERENCE TO RELATED APPLICATIONS

This application claims priority to DE application Serial No. 102020123220.9 filed Sep. 4, 2020, the disclosure of which is hereby incorporated in its entirety by reference herein.

### TECHNICAL FIELD

Embodiments as disclosed herein relate to a method for managing a memory for an onboard computer in a motor vehicle. The invention is usable in microelectronics, in particular in the field of motor vehicle electronics.

### BACKGROUND

Memory systems are used for storing software and application data within onboard computers of vehicles. Since an onboard computer is fundamentally not to be replaced during the entire service life (lifetime) of the vehicle, the lifetime of an onboard computer is significantly longer than the lifetime of other computers. Within this time, non-volatile memory such as NAND flash memory, as used therein, however, can reach the maximum number of write/erase cycles and fail. To prevent this, the memory has to be replaced in a timely manner beforehand.

The replacement intervals are shorter in newer systems because newer flash memories have smaller structural sizes, less charge stored in the floating gate, and therefore fewer write/erase cycles, and further because more data are written and read.

The maximum service life also depends strongly on the installed application software and on the usage behavior, which makes it difficult to plan replacement intervals. The system therefore has to determine the period of time dynamically, so that the end of the lifetime does not occur as a surprise to the user.

In fact, more write operations have to be carried out in the memory component than are visible to a processor (or host) that monitors the memory. This is because the memory is only writeable in blocks (or pages) that define a minimum size for the data writable at once. If smaller amounts of data or amounts of data that do not represent an integer multiple of the page size are written, more memory cells thus have to be written than necessary. In addition, measures in the storage device (e.g., wear leveling, bad block management) require additional operations. Using special buffers to temporarily store data is known. However, these buffers take up storage space and are themselves subjected to a large number of read and write procedures

Memory devices having a higher number of possible read-write cycles are also known, for example improved NAND flash, magnetoresistive memory, or Ferroelectric RAM (or FeRAM). However, these devices have a significantly lower storage density.

It is an object of the invention to at least alleviate these disadvantages.

### SUMMARY

One invention is specified in the independent claims. Advantageous embodiments can be found in the dependent claims.

According to one embodiment, a method for managing a memory for an onboard computer in a motor vehicle is provided. A degree of wear of the memory, which depends on the amount of data written into the memory, is determined at regular time intervals.

If the degree of wear exceeds a specified target value, a coding of one or more cells of the memory is changed from a physical coding of higher density to a physical coding of lower density.

In this way, the option of a memory of storing several bits per memory cell is used. In one embodiment, the memory can be a flash-based memory, for example, a solid-state disk. Here, the 2ⁿ charge states of a cell or a capacitor represent n bits. However, the wear of the insulation of the capacitor of a memory cell has the result that the charge can no longer be held continuously. As a result, after the wear has occurred, it is no longer possible to distinguish between multiple charge states when reading. The occurrence of wear thus defines the expected service life end of the memory. Since the wear depends on the amount of data written, the service life depends on the user behavior. However, if the coding of the cell is changed so that only a smaller number of charge states are used, for example, two charge states are stored corresponding to one bit, the service life is extended, since, even in the event of wear, it is possible even longer to distinguish between two charge states than between a larger number of charge states. Reducing the coding to a lower density coding thus ensures that the service life increases, but the storage space decreases. The fact that the service life increases more than the density decreases is used here. For example, for a NAND flash, reducing the storage density from 3 bits to 1 bit can increase the service life by a factor of 30. The invention is not limited to a specific memory design. It is applicable to any memory storing a plurality of bits per cell. It is advantageous in any such memory that has wear.

According to the embodiment, the memory is thus operated at a high density and the number of terabytes written so far is monitored. If a specified value has been reached, the memory can no longer be operated at the high density: The cells are so worn out that it is no longer possible to distinguish between a high number of states per cell. If, for example, the oxide layer in a flash memory is permanently changed in such a way that an increased leakage current occurs, each cell thus loses more charge between accesses. As a result, the charge level fluctuates more and only a smaller number of states is still distinguishable. The memory can therefore no longer be operated in the coding having high density. Therefore, the coding is changed to a coding having lower density.

The time intervals at which the degree of wear is determined can be specified or adjusted according to the user behavior. In particular, the time intervals can be selected to be small enough to ensure that, even with intensive use of the memory, exceeding the setpoint value is detected in a timely manner, so that the coding can be changed before data are incorrectly written and read.

In one embodiment, the degree of wear is formed by a proportion of the number of the amount of data written in the memory to a number of the amount of data writeable in the memory up to an expected service life end using the coding of higher density.

The target value for the degree of wear can be fixedly specified and can be, for example, 90% of the total possible terabytes written. However, lower or higher values can also be used. This establishes a safety margin to the probable maximum value from which errors are to be expected. This is particularly useful for motor vehicles, where safety-critical systems are to be operated with as few errors as possible. This is also advantageous if the change in the coding is furthermore to be dependent on a decision by the user. In this case, the user can either change the encoding somewhat beforehand to ensure high reliability, or delay the change to profit from the available storage space somewhat longer. In addition, the service life can also increase with a coding having lower density because the number of accesses per cell decreases: The software on the computer has less storage space available, and thus there are potentially fewer accesses. However, this depends on usage behavior, since changing the coding only results in fewer accesses if the storage space is actually used and does not remain empty to a sufficiently large extent.

This entails that the memory can be used over a longer time. An immediate failure is avoided, and the memory can be replaced during a previously planned maintenance, such as a routine inspection of the vehicle. This is advantageous for operational safety. In addition, the wear of the memory becomes better recognizable to the user by gradually reducing the memory space.

In another embodiment, the determination of a degree of wear comprises reading out a value that is stored in a register belonging to the memory of the written amount of data.

For this purpose, a “health descriptor” can be used in particular, which is defined for Universal Flash Storage (UFS) by standards, for example JEDEC TESD 220C for UFS 2.1.

In another embodiment, the written and/or writable amount of data is specified as a value for the terabytes written (Terabytes Written, “TBW”). The terabytes written are a numeric value for the wear or the possible wear of a memory. The previously written terabytes are the data previously written into a memory by storing (i.e., programming) or erasing, that is to say the sum of the product calculated for each memory cell from the number of write/erase cycles and the number of bits stored in a cell. The amount of data writable into the memory can be specified as the implementable number of terabytes written into the memory (implementable TBW). The amount of data written into the memory can also be expressed as a percentage proportion of the writable amount of data (quotient TBW/implementable TBW).

In a further embodiment of the invention, determining a degree of wear comprises determining a bit error rate. As a result, the memory can continue to be operated even after the end of its service life until the bit error rate reaches a predetermined threshold value. This criterion can be combined with the criterion of the amount of data. In this way, an advantageous compromise between storage space and reliability can be achieved.

In a further embodiment, changing the coding includes changing a number of states per cell from a higher number of states to a lower number of states.

This is particularly the case for flash memory. A cell can store a plurality of n bits in that 2ⁿ different charge states are implementable. Each charge state corresponds to a value for the charge. In order to implement a certain error tolerance, each charge state is assigned an interval of values for the charge. If, however, the memory cell is already worn, i.e., the insulating property of the oxide layer is poor, the charge is not retained and the value can change from one predetermined interval to another. This results in a bit error. If the memory is operated using a coding having a lower number of states, the intervals and thus the error tolerance are greater. In the case of a flash memory, the already known formats (single-level cell “SLC” with 1 bit per cell, multi-level cell “MLC” with two bits per cell, triple-level cell with 3 bits per cell) are thus used. However, this feature is also transferable to other types of memory, such as phase change memory (PCM).

In a further embodiment, if the degree of wear exceeds a predetermined target value, a total number of terabytes writable into the memory up to an expected end of lifetime using the coding of lower density is determined and stored in the memory. After the coding has been changed, the degree of wear is formed by a proportion of the number of terabytes written into the memory of the total number of terabytes writable into the memory using the coding of higher density up to an expected service life end.

This creates the conditions for using the method multiple times. At a first wear state, the coding can thus initially be reduced from, for example, 4 bits per cell to 2 bits per cell, and if a second wear state occurs, to 1 bit per cell. The second wear state is determinable in that the factor by which the number of write/erase cycles increases due to changing the coding (a value empirically established using prototypes for a certain memory type) is stored in the memory or provided in another way. If the coding is changed, the tracking of the terabytes written, for example, by the health descriptor, is also adapted thereto. The increase in terabytes written will continue to be monitored and the coding will be reduced from 2 bits per cell to 1 bit per cell as soon as necessary.

The expected lifetime can be specified by dividing the previous service life by the terabytes written (these as a proportion of the total possible terabytes written). This creates a prediction of how long the memory will still function if the current usage behavior continues. The previous service life and the percentage can be stored in the system.

In another embodiment, a number of the terabytes that are expected to be written after a target service life has expired is determined as the product of the terabytes previously written on average per unit of time and the target service life. If the number of terabytes that are expected to be written after a target service life has expired is greater than the total number of terabytes that can be written to the memory using the lower density coding until an expected service life end, a warning is output.

In contrast to the expected lifetime, the target service life is a specified value that indicates how long the memory should be used. In particular, an interval between two maintenance procedures on the memory can be established. If the memory is installed in a motor vehicle, the time up to a planned inspection of the vehicle can be selected as the target service life. Alternatively, the entire lifetime of the vehicle can also be selected. The terabytes that are expected to be written after the target service life has expired can be compared to the maximum writable written terabytes that are still available. If it is now found that, even if the coding is changed, the memory cannot be operated until the end of the target service life, a warning is output which indicates the need to replace the memory prematurely.

In another embodiment, the cells form a partition, and the method furthermore comprises determining a size of the partition as the highest value of the data simultaneously stored in the memory in a predetermined period of time by one or more predetermined programs executed on the onboard computer.

This allows the memory to be partitioned. For an area for particularly safety-critical data, the coding is changed according to an embodiment particularly early with a particularly large safety margin up to the predicted expiration of the lifetime. For a further area that is used for data from a system that is not safety-critical (for example multimedia system), the coding is not changed or is only changed after a minimum number of read errors have occurred. The storage space is therefore kept at a high level for as long as possible.

In another embodiment, a setting is also queried by a user, which indicates whether the coding is changeable. The change only takes place if the setting indicates that the coding is changeable.

In another embodiment, the memory is a flash memory.

In another embodiment, the terabytes written include write operations that are carried out by a controller to manage the memory. In particular, the terabytes written can include write operations due to wear leveling, management of defective blocks of the memory, and optimization processes. These processes are carried out by a memory controller and are generally not visible to the operating systems and application programs running on the main processor, which is separate therefrom. However, they make a significant contribution to memory accesses (write amplification). They are included in the number of terabytes written.

In another embodiment, a data storage device is provided. The data storage device comprises a memory and a controller which is designed to carry out the method.

### BRIEF DESCRIPTION OF THE DRAWINGS

Exemplary embodiments of the invention are described in more detail with reference to the accompanying drawings. In the figures:

FIG. 1 shows a flow chart which illustrates a method for changing the coding according to an embodiment;

FIG. 2 shows a flow chart which illustrates a method for partitioning and changing the coding according to an embodiment;

FIG. 3 shows a block diagram which illustrates a memory component according to an embodiment; and

FIG. 4 shows a block diagram which illustrates a computer according to an embodiment.

### DETAILED DESCRIPTION

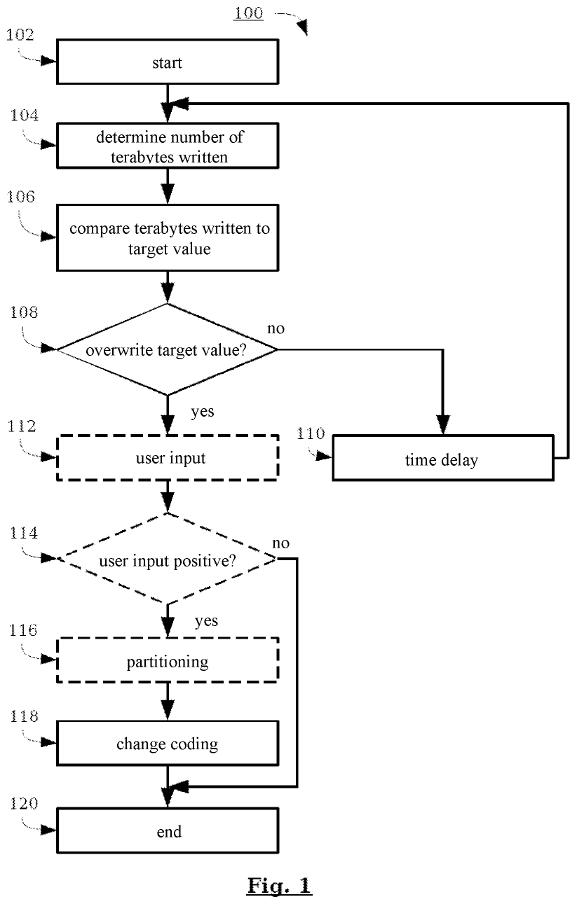

FIG. 1 shows a flow chart which illustrates a method 100 for changing a coding according to an embodiment. The method begins, 102, with startup of the memory. First, a degree of wear of the memory is determined, 104. For this purpose, the number of terabytes written so far is loaded as a percentage of the terabytes possibly written until the expected service life end of the memory from a register provided for this purpose, for example “health descriptor”. It is then checked, 206, whether the number of terabytes written so far exceeds a specified target value. The target value is set in such a way that the target value is reached on or before the expected service life end. If, for example, the reduction in storage space is initially to be limited, a high target value can be specified. If it is to be ensured that the memory component works without errors, a lower target value can be specified.

If the target value is not reached, the coding is not changed. The method 100 is continued by first waiting, 110, for a specified time. Then the process starts all over again. The time delay can be settable during the initial configuration of the system and also later by the user. It can also be adapted to user behavior during operation.

If the target service life is exceeded, this is displayed to the user and an input is requested in which he can confirm or prevent the change of the coding, 112, 114. This gives the user the opportunity to check whether the user would like to continue using the memory with the current memory capacity and in return accept an earlier service life end, for example because the replacement of the memory is planned in any case. In this case, the method is terminated. However, the steps of displaying and confirming by the user are optional. If the method 100 is continued, the memory is optionally divided, 116, into two partitions. One partition remains unchanged, and the coding is changed, 118, from the previous coding to the target coding in the other. Alternatively, the coding of the entire memory can be changed. After the coding has been changed, the method 100 in the exemplary embodiment comes to an end, 120.

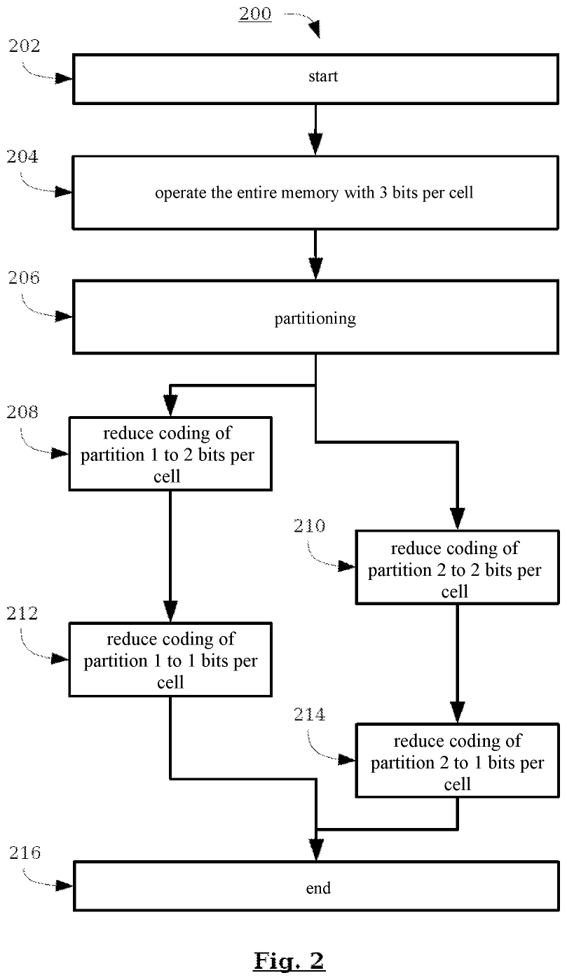

FIG. 2 shows a flow chart which illustrates a method 200 for partitioning and changing the coding according to an embodiment. The method 200 represents the repeated application of the method in FIG. 1. Initially, 202, the memory is operated at 3 bits per cell, 204. Regular checks are carried out to determine whether the amount of data written exceeds a target value. If this is the case, the memory is first divided, 206, into two partitions. The size of the first partition is selected so that the data of a predetermined group of programs (e.g., such as the operating system, security-critical applications) can be accommodated in the partition. For this purpose, the maximum value plus a safety margin can be set as the partition size. The coding of the first partition is reduced, 208, from 3 bits per cell to 2 bits per cell. The second partition continues to be operated with 3 bits per cell. The coding of the second partition will only be reduced, 210, to 2 bits per cell at a later point in time. This can be triggered by an error correction (error correcting code “ECC”) establishing that an error rate exceeds a specified threshold value.

If one or more partitions are operated with 2 bits per cell, service life end can also be reached here. This is because the cells can exhibit leakage currents due to wear, which also no longer allow reliable reading of 2 bits per cell. This happens after a significantly larger number of write/erase cycles. Due to the change of the coding, for example, the storage capacity can be reduced to two-thirds, but the number of the write/erase cycles can be increased by a factor of 30. This entails that the writable amount of data, and thus the target value of the writable data, increases by a factor of 20 until the next change of the coding. During operation using the coding with reduced density (2 bits per cell), the amount of data written is continuously tracked and it is determined whether the new target value has been exceeded. If the new target value is exceeded, the coding of the first partition is thus reduced, 212, to 1 bit per cell. For the second partition, the coding is again only reduced, 214, when a certain error rate occurs. The memory is then operated with a coding of 1 bit per cell.

This method 200 only represents one embodiment. Other combinations of different conditions for a change in the coding can also be selected. Thus, for example, the coding can also be changed for the second partition as soon as the amount of data written in this partition exceeds a target value. However, this can be chosen differently, for example, having a smaller safety margin to an expected service life end.

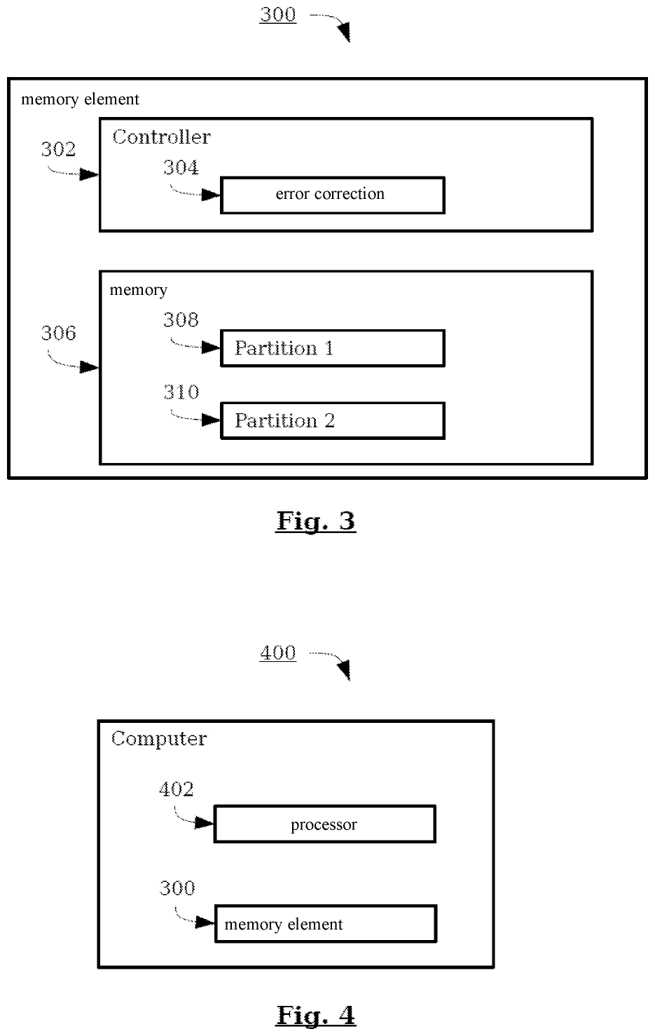

FIGS. 3 and 4 show block diagrams which illustrate a memory component 300 and a computer 400 according to one embodiment. The computer 400 has a processor 402 which is designed to run a hypervisor, one or more operating systems, and/or application software. A memory component 300 having a controller 302 and a memory 306 is used to store the programs and the data processed thereby. The controller 302 can have an error correction mechanism (or error correcting code “ECC”) 304. The memory 306 can be divided into two partitions 308 and 310, the coding of which is changed. The memory 306 can be a non-volatile memory, in particular a NAND flash. The number of memory operations (particularly write and erase) initiated by the software executed by processor 402 that is visible to the software is generally less than the number of memory operations that actually take place in memory 306 and is therefore not a realistic measure of the wear of the memory 306. This is due to the fact that only blocks of a minimum size can be written, that is to say, with amounts of data that are smaller than the minimum size, more data are actually overwritten in the memory 306 than are visible to the processor 402 (write amplification). The controller 302 also executes management operations such as wear leveling and bad block locking, which increase the number of terabytes actually written. If a method as set forth herein is therefore carried out in processor 402, the number of terabytes written has to be determined in a way that takes this circumstance into account. For this purpose, a value stored in the memory 306 can be used for the proportion of terabytes that have already been written. For example, the UFS 2.1 compatible storage standard JEDEC JESD 220C describes a health descriptor that specifies p in 10% steps. The JEDEC JESD 84-B51A standard applies to eMMC 5.1 and allows the value p to be specified in 1% steps.

### LIST OF REFERENCE NUMERALS

100 method for changing a coding
102-120 steps of a method for changing a coding
200 method for determining a partitioning and changing the coding
202-216 steps of a method for determining a partitioning and changing the coding
300 memory
302 controller
304 error correction
306 memory
308 partition 1
310 partition 2
400 computer
402 processor

What is claimed is:

1. A method for managing a memory for an onboard computer in a motor vehicle, the method comprising:
determining, at regular time intervals, a degree of wear of the memory as a function of an amount of data written into the memory; and
if the degree of wear exceeds a specified target value, changing a coding of one or more cells of the memory from a physical coding of higher density to a physical coding of lower density.

2. The method of claim 1, wherein the degree of wear is formed by a proportion of the amount of data written in the memory to the amount of data writeable in the memory up to an expected service life end using the physical coding of higher density.

3. The method of claim 2 further comprising:
if the degree of wear exceeds a specified target value: determining, in the memory, a total amount of data writable into the memory up to an expected service life end using the coding of lower density,
wherein the degree of wear after the change of the coding is formed by a proportion of the amount of data written into the memory to the amount of data writable into the memory up to an expected service life end using the coding of lower density.

4. The method of claim 3, further comprising determining the amount of data that is expected to be written up to an expiration of a target service life as a product of the amount of data written up to this point on average per unit of time and the target service life;
if the amount of data that is expected to be written up to the expiration of a target service life is greater than the total amount of data writable into the memory up to the expected service life end using the coding of lower density:
output of a warning.

5. The method of claim 1, wherein the determination of a degree of wear comprises reading out a value which indicates the amount of data written into the memory and which is stored in a register belonging to the memory.

6. The method of claim 1, wherein at least one of the amount of data written into the memory is specified as a number of terabytes written into the memory, and the amount of data writeable into the memory is specified as an implementable number of terabytes written into the memory.

7. The method of claim 1, wherein determining the degree of wear comprises determining a bit error rate.

8. The method of claim 1, wherein changing the coding includes changing a number of states per cell from a higher number of states to a lower number of states.

9. The method of claim 1, wherein the one or more cells form a partition, the method further comprising:
determining a size of the partition corresponding to a maximum amount of data stored in the memory simultaneously in a specified period of time by one or more specified programs executed on the onboard computer.

10. The method of claim 1 further comprising querying a user-defined setting which specifies whether the physical coding is changeable. wherein the change only takes place if the user-defined setting specifies that the physical coding is changeable.

11. The method of claim 1, wherein the memory is a flash memory.

12. The method of claim 1, wherein the writing of the amount of data comprises write operations performed by a controller to manage the memory.

13. The method of claim 12, wherein writing the amount of data comprises write operations due to wear leveling, management of bad blocks of the memory, and optimization operations performed by a controller to manage the memory.

14. A data storage device comprising:
a memory; and
a controller which is designed to carry out a method as claimed in claim 1.

15. A data storage device comprising:
a memory; and
a controller being operably coupled with the memory, the controller being programmed to:
determine, at regular time intervals, a degree of wear of the memory as a function of an amount of data written into the memory; and
if the degree of wear exceeds a specified target value, change a coding of one or more cells of the memory from a physical coding of higher density to a physical coding of lower density.

16. The data storage device of claim 15, wherein the degree of wear is formed by a proportion of the amount of data written in the memory to the amount of data writeable in the memory up to an expected service life end using the physical coding of higher density.

17. The data storage device of claim 16, wherein the controller is further programmed to, if the degree of wear exceeds a specified target value, determine, in the memory, a total amount of data writable into the memory up to an expected service life end using the coding of lower density,
wherein the degree of wear after the change of the coding is formed by a proportion of the amount of data written into the memory to the amount of data writable into the memory up to an expected service life end using the coding of lower density.

18. The data storage device of claim 17, wherein the controller is further programmed to determine the amount of data that is expected to be written up to an expiration of a target service life as a product of the amount of data written up to this point on average per unit of time and the target service life; and
if the amount of data that is expected to be written up to the expiration of a target service life is greater than the total amount of data writable into the memory up to the expected service life end using the coding of lower density, then the controller is further programmed to output of a warning.

19. The data storage device of claim 15, wherein the determination of a degree of wear comprises reading out a value which indicates the amount of data written into the memory and which is stored in a register belonging to the memory.

20. A method for managing a memory for an onboard computer in a motor vehicle, the method comprising:
determining, at regular time intervals, a degree of wear of the memory as a function of an amount of data written into the memory; and
if the degree of wear exceeds a specified target value, changing a coding of one or more cells of the memory from a physical coding of a first density to a physical coding of a second density, wherein the first density is greater than the second density.
